(19) United States
(12) Patent Application Publication
(10) Pub. No.: US 2025/0393350 A1
(43) Pub. Date: Dec. 25, 2025

(54) APPARATUS AND METHOD FOR MANUFACTURING DISPLAY DEVICE

(71) Applicant: Samsung Display Co., Ltd., Yongin-si (KR)

(72) Inventors: Yeongmin Kim, Yongin-si (KR); Dongwook Kim, Yongin-si (KR); Sangjin Han, Yongin-si (KR); Mingyoun Kang, Yongin-si (KR); Shinyang Kim, Yongin-si (KR); Sungho Park, Yongin-si (KR)

(73) Assignee: Samsung Display Co., Ltd., Yongin-si (KR)

(21) Appl. No.: 19/016,661

(22) Filed: Jan. 10, 2025

(30) Foreign Application Priority Data
Jun. 25, 2024 (KR) 10-2024-0083032

(51) Int. Cl. H10H 29/02; H01L 21/683

(52) U.S. Cl. CPC H10H 29/02; H01L 21/6831

(57) ABSTRACT

An apparatus for manufacturing a display device includes a chamber, an electrostatic chuck disposed in the chamber, the electrostatic chuck holding a display substrate in close contact with a surface of the electrostatic chuck and including chuck zones, a detection portion including sensors connected to corresponding chuck zones among the chuck zones, a power portion including power sources connected to the chuck zones and applies voltages to the chuck zones, and a control portion connected to the detection portion and the power portion, the control portion detects a defective chuck zone among the chuck zones based on information received from the detection portion, and controls the power portion to adjust a voltage applied to another chuck zone adjacent to the defective chuck zone.

### CROSS-REFERENCE TO RELATED APPLICATION(S)

This application claims priority to and benefits of Korean Patent Application No. 10-2024-0083032 under 35 USC § 119, filed on Jun. 25, 2024, in the Korean Intellectual Property Office, the entire contents of which are incorporated herein by reference.

### BACKGROUND

### 1. Technical Field

One or more embodiments relate to an apparatus for manufacturing a display device and a method of manufacturing a display device. One or more embodiments also relate to an electronic device manufactured by the method. The apparatus for manufacturing a display device according to the disclosure may include an electrostatic chuck. The method of manufacturing a display device according to the disclosure may include a method of operating an electrostatic chuck.

### 2. Description of the Related Art

In addition to manufacturing of various semiconductor chips, manufacturing of display devices or display panels including light-emitting diodes can be performed in process equipment or in a chamber.

In a process of manufacturing semiconductor devices and a process of manufacturing display devices, a chuck is used to secure a wafer or substrate to a stage. For example, the chuck may include a mechanical chuck that uses clamps or a vacuum, and/or an electric chuck that uses an electrical force to secure the substrate to the stage. An electrostatic chuck, which is a type of electric chuck, can secure the substrate to the stage by using an electrostatic force.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An electrostatic chuck can apply an electrostatic force to a substrate by making contact with the substrate. The electrostatic chuck may be divided into a plurality of zones, and a voltage can be applied to each zone individually. Defects such as arcing or short circuits may occur in electrostatic chucks due to contamination by particles generated during a process of manufacturing a display device or due to other causes. A zone of the chuck where the defect occurs may not be able to apply an appropriate chucking force to the substrate. In case that the appropriate chucking force is not applied to the substrate, the substrate may not stick to the electrostatic chuck and may become separated from the electrostatic chuck. This may lead to sagging in local areas of the substrate. A solution to prevent a display substrate from failing to make contact with the electrostatic chuck and sagging in an area overlapping the chuck zone where the defect has occurred is required.

Additional aspects will be set forth in part in the description which follows and, in part, will be apparent from the description, or may be learned by practice of the presented embodiments.

According to one or more embodiments, an apparatus for manufacturing a display device may include a chamber; an electrostatic chuck disposed in the chamber; the electrostatic chuck holding a display substrate in close contact with a surface of the electrostatic chuck and including a plurality of chuck zones; a detection portion including a plurality of sensors connected to corresponding chuck zones of the plurality of chuck zones; a power portion including a plurality of power sources connected to the plurality of chuck zones and applies voltage to the plurality of chuck zones; and a control portion connected to the detection portion and the power portion, wherein the control portion detects a defective chuck zone among the plurality of chuck zones based on information received from the detection portion, and controls the power portion to adjust a voltage applied to another chuck zone adjacent to the defective chuck zone.

In an embodiment, the detection portion may have a number of sensors equal to a number of the plurality of chuck zones and one sensor may be connected to one chuck zone.

In an embodiment, the power portion may have a number of power sources equal to or less than a number of the plurality of chuck zones and one power source may be connected to one or more chuck zones of the plurality of chuck zones.

In an embodiment, at least one of the plurality of power sources may have a switching circuit connected to two or more of the plurality of chuck zones and controls voltage applied to each of the plurality of chuck zones connected to the switching circuit.

In an embodiment, the plurality of chuck zones may include eight or more chuck zones.

In an embodiment, at least one of the plurality of sensors may detect a current in a corresponding chuck zone of the plurality of chuck zones.

In an embodiment, the control portion may cut off a voltage in the defective chuck zone.

In an embodiment, the control portion may increase the voltage applied to the other chuck zone adjacent to the defective chuck zone.

In an embodiment, the plurality of chuck zones may include positive chuck zones that receive a positive voltage and negative chuck zones that receive a negative voltage, and the positive chuck zones and the negative chuck zones may be disposed alternately along a direction.

In an embodiment, the apparatus may further include a deposition mask disposed in the chamber, and the display substrate may be disposed between the electrostatic chuck and the deposition mask.

According to one or more embodiments, a method of manufacturing a display device may include loading a display substrate into a chamber in which an electrostatic chuck including a plurality of chuck zones is disposed; inspecting the plurality of chuck zones using a plurality of sensors connected to corresponding chuck zones of the plurality of chuck zones; controlling a plurality of power sources connected to the plurality of chuck zones to adjust a voltage applied to another chuck zone adjacent to a defective chuck zone of the plurality of chuck zones; and bringing the display substrate and the electrostatic chuck into proximity.

In an embodiment, a number of the plurality of chuck zones and a number of above plurality of sensors may be equal to each other.

In an embodiment, a number of the plurality of power sources may be equal to or less than a number of the plurality of chuck zones, and one power source may be connected to one or more chuck zones of the plurality of chuck zones.

In an embodiment, at least one of the plurality of power sources may have a switching circuit connected to two or more of the plurality of chuck zones and controls voltage applied to each of the plurality of chuck zones connected.

In an embodiment, the method may further include applying voltage to the plurality of chuck zones.

In an embodiment, the method may further include detecting a current of the plurality of chuck zones.

In an embodiment, controlling the plurality of power sources may include cutting off a voltage of the defective chuck zone.

In an embodiment, controlling the plurality of power sources may further include increasing the voltage applied to the other chuck zone adjacent to the defective chuck zone.

In an embodiment, inspecting the plurality of chuck zones may include checking whether the electrostatic chuck and the display substrate are in contact with each of the plurality of chuck zones.

In an embodiment, the method may further include attaching a deposition mask to the display substrate and depositing a deposition material on the display substrate.

In an embodiment, an electronic device may include the display device manufactured by the method.

In an embodiment, the electronic device may be at least one of a flat panel display, a curved display, a computer monitor, a medical monitor, a television, a billboard, an indoor light, an outdoor light, an indoor signaling light, an outdoor signaling light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, or a signboard.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic cross-sectional view of an apparatus for manufacturing a display device according to an embodiment;

FIG. 2 is a schematic cross-sectional view of an electrostatic chuck according to an embodiment;

FIG. 3A is a schematic rear view of an electrostatic chuck according to an embodiment;

FIG. 3B is a schematic rear view of an electrostatic chuck according to an embodiment;

FIG. 3C is a schematic rear view of an electrostatic chuck according to an embodiment;

FIG. 4 is a schematic diagram of an electrostatic chuck system according to an embodiment;

FIG. 5 is a schematic diagram of an electrostatic chuck system according to an embodiment;

FIG. 6 is a schematic diagram of an electrostatic chuck system according to an embodiment;

FIG. 7 is a schematic diagram of an electrostatic chuck system according to an embodiment;

FIG. 8 is a flowchart of operations of a method of manufacturing a display device, according to an embodiment;

FIG. 9 is a schematic diagram of operations of a method of manufacturing a display device, according to an embodiment;

FIG. 10 is a schematic plan view of a display device manufactured using an apparatus for manufacturing a display device, according to an embodiment;

FIG. 11 is a schematic cross-sectional view of the display device of FIG. 10 taken along line X-X′; and

FIGS. 12 and 13 are perspective views illustrating an electronic device.

### DETAILED DESCRIPTION OF THE EMBODIMENTS

As the disclosure allows for various changes and numerous embodiments, given embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof may be omitted.

Although the terms “first,” “second,” etc. may be used to describe various elements, these elements should not be limited by these terms. These terms are only used to distinguish one element from another. For example, a first element may be referred to as a second element, and similarly, a second element may be referred to as a first element without departing from the scope of the disclosure.

As used herein, the singular forms “a,” “an,” and “the” are intended to include the plural forms as well, unless the context clearly indicates otherwise.

It will be understood that the terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be further understood that, when a layer, region, or component is referred to as being “on” another layer, region, or component, it may be directly on the other layer, region, or component, or may be indirectly on the other layer, region, or component with intervening layers, regions, or components therebetween.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

Sizes of components in the drawings may be exaggerated or reduced for convenience of explanation. For example, because sizes and thicknesses of components in the drawings are arbitrarily illustrated for convenience of explanation, the disclosure is not limited thereto.

When a given embodiment may be implemented differently, a specific process order may be different from the described order. For example, two consecutively described processes may be performed substantially at the same time or may be performed in an order opposite to the described order.

“A and/or B” is used herein to select only A, select only B, or select both A and B. “At least one of A or B” is used to select only A, select only B, or select both A and B.

In the following embodiments, when a layer, a region, a component, etc. are connected to each other, the layer, the region, and the components may be directly connected to each other and/or the layer, the region, and the components may be indirectly connected to each other with other layers, and other regions and other components may be between the layer, the region, and the components. For example, when a layer, a region, a component, etc. are electrically connected to each other in the specification, the layer, the region, the component, etc. may be directly electrically connected to each other, and/or the layer, the region, the component, etc. may be indirectly electrically connected to each other with other layers, and other regions and other components may be between the layer, the region, and the components.

The x direction, the y direction, and the z direction are not limited to three directions on a Cartesian coordinate system, and may be interpreted in a broad sense including the same. For example, the x direction, the y direction, and the z direction may be perpendicular to each other, but may refer to different directions that are not perpendicular to each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

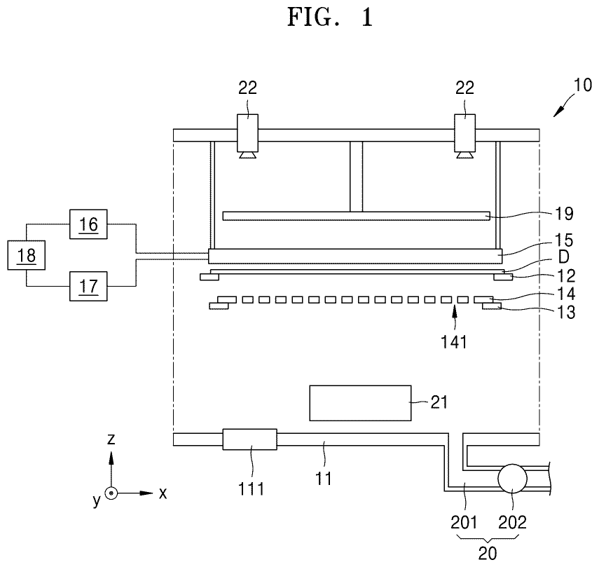

FIG. 1 is a schematic cross-sectional view of an apparatus for manufacturing a display device according to an embodiment.

Referring to FIG. 1, the apparatus 10 for manufacturing a display device may include a chamber 11, a first support portion 12, a second support portion 13, a deposition mask 14, an electrostatic chuck 15, a detection portion 16, a power portion 17, a control portion 18, a magnetic force portion 19, a pressure control portion 20, a deposition source 21, and a vision portion 22.

The chamber 11 can provide a space in which a process performed by the apparatus 10 for manufacturing a display device can be performed. In an embodiment, the chamber 11 may be partially open. In an embodiment, a gate valve 111 may be installed in an opened portion of the chamber 11. In this case, the opened portion of the chamber 11 can be opened or closed depending on the operation of the gate valve 111.

The first support portion 12 may support and secure a display substrate D. In an embodiment, the first support portion 12 may be in the form of a frame fixed inside the chamber 11. In an embodiment, the first support portion 12 may be in the form of a shuttle on which the display substrate D is secured and which is configured to move linearly in the chamber 11. In an embodiment, the first support portion 12 may be arranged (or disposed) in the chamber 11 so as to be able to ascend or descend in the chamber 11. For convenience of explanation, the case in which the first support portion 12 is fixed inside the chamber 11 is described in detail below.

The second support portion 13 may support and secure the deposition mask 14. In an embodiment, the second support portion 13 may be arranged inside of the chamber 11. In an embodiment, the second support portion 13 can fine-tune the position of the deposition mask 14. In an embodiment, the second support portion 13 may be provided with a separate driving unit or alignment unit, etc., to enable the deposition mask 14 to move in different directions. In an embodiment, the second support portion 13 may also be in the form of a shuttle. In this case, the deposition mask 14 may be secured on the second support portion 13, and the second support portion 13 may transport the deposition mask 14. For example, the second support portion 13 may be moved outside the chamber 11 and enter the chamber 11 from outside the chamber 11 after the deposition mask 14 is secured on the second support portion 13.

The first support portion 12 and the second support portion 13 may also be integral. In this case, the first support portion 12 and the second support portion 13 may include movable shuttles. In this case, the first support portion 12 and the second support portion 13 may include a structure that fixes the deposition mask 14 and the display substrate D in a state where the display substrate D is secured on the deposition mask 14, and may be able to linearly move the display substrate D and the deposition mask 14 together.

Hereinafter, for convenience of explanation, the first support portion 12 and the second support portion 13 are formed to be distinct from each other and are arranged at different positions inside of the chamber 11.

The display substrate D may be disposed on the first support portion 12. The display substrate D may be a processing subject of the apparatus 10 for manufacturing a display device, rather than a component of the apparatus 10 for manufacturing a display device. The deposition mask 14 can be disposed on the second support portion 13. The deposition mask 14 may include openings 141 that allow a deposition material to pass through so as to be deposited on the display substrate D. The openings (141) of the deposition mask (14) may define a deposition area where the deposition material is deposited.

In an embodiment, the first support portion 12 can be disposed in the z direction with respect to the second support portion 13. In an embodiment, the display substrate D may be disposed in the z direction with respect to the deposition mask 14.

The electrostatic chuck 15 may be disposed in the z direction with respect to the display substrate D. For example, the display substrate D may be disposed between the electrostatic chuck 15 and the deposition mask 14. The electrostatic chuck 15 may hold the display substrate D using electrostatic force. The electrostatic chuck 15 can prevent the display substrate D from moving during the process of driving the apparatus 10 for manufacturing a display device, for example, during the process of depositing a deposition material on the display substrate D. The electrostatic chuck 15 can also bring the display substrate D and the deposition mask into close contact.

The electrostatic chuck 15 can be connected to the detection portion 16 and the power portion 17. In an embodiment, the detection portion 16 may include sensors as described below. In an embodiment, the detection portion 16 may detect given conditions (for example, voltage, current, and/or charge) of the electrostatic chuck 15. In an embodiment, the power portion 17 may include power sources as described below. In an embodiment, the power portion 17 may apply voltage to the electrostatic chuck 15. The detection portion 16 and power portion 17 may be connected to the control portion 18.

The control portion 18 may control the power portion 17 based on information obtained by the detection portion 16. In an embodiment, the electrostatic chuck 15 may be connected to the detection portion 16 via a conductive cable. In an embodiment, the electrostatic chuck 15 may be connected to a power portion 17 via a conductive cable. In an embodiment, the detection portion 16, power portion 17, and control portion 18 may be arranged outside of the chamber 11. The term ‘electrostatic chuck system’ used hereinafter in the disclosure may refer to a system including an electrostatic chuck 15, a detection portion 16, a power portion 17, and a control portion 18.

The magnetic force portion 19 overlaps the electrostatic chuck 15 and may be disposed in the z direction with respect to the electrostatic chuck 15. For example, the electrostatic chuck 15 may be disposed between the magnetic force portion 19 and the display substrate D. In an embodiment, the magnetic force portion 19 may use magnetic force to bring the display substrate D and the deposition mask 14 into close contact. In other words, the display substrate D and the deposition mask 14 may be brought into close contact with each other by the electrostatic force of the electrostatic chuck 15 and the magnetic force of the magnetic force portion 19. In an embodiment, unlike an embodiment shown in FIG. 1, the magnetic force portion 19 may be omitted. In an embodiment, the electrostatic chuck 15 and the magnetic force portion 19 may be driven separately.

The pressure control portion 20 may be connected to the chamber 11 and may control the pressure inside the chamber 11. In an embodiment, the pressure control portion 20 may include a connection pipe 201 connected to the chamber 11, and a pump 202 disposed at the connection pipe 201.

The deposition source 21 may be arranged in the chamber 11 and may be disposed in an opposite direction of the z direction with respect to the deposition mask 14. For example, the deposition mask 14 may be disposed between the display substrate D and the deposition source 21. In an embodiment, the deposition source 21 may store a deposition material inside. In an embodiment, the deposition source 21 may be supplied with the deposition material from outside the chamber 11. In an embodiment, the deposition source 21 may be equipped with a heater for heating the deposition material. In an embodiment, the deposition source 21 may have a nozzle that sprays the deposition material toward the deposition mask 14 and the display substrate D (for example, in the z direction).

The vision portion 22 may be installed in the chamber 11 and may film the positions of the display substrate D and the deposition mask 14. In an embodiment, the vision portion 22 may be arranged on the upper side of the chamber 11, for example, on the z-direction side. In an embodiment, the vision portion 22 may be provided with a camera that films the display substrate D, the electrostatic chuck 15, and the deposition mask 14. In an embodiment, the positions of the display substrate D, the electrostatic chuck 15, and the deposition mask 14 may be identified based on images captured by the vision portion 22. In an embodiment, a position of the display substrate D on the first support portion 12, a position of the deposition mask 14 on the second support portion 13, or a position of the electrostatic chuck 15 may be adjusted based on the images.

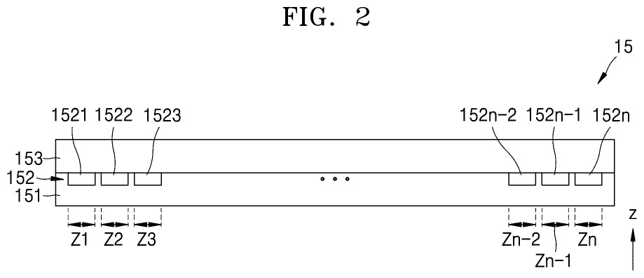

FIG. 2 is a schematic cross-sectional view of an electrostatic chuck according to an embodiment.

Referring to FIG. 2, the electrostatic chuck 15 may include a first insulating layer 151, a second insulating layer 153, and an electrode layer 152 disposed between the first insulating layer 151 and the second insulating layer 153. The electrode layer 152 may include electrodes 1521 to 152n spaced apart from each other. Although not shown in FIG. 2, the electrostatic chuck 15 may be provided with wires connected to the electrodes 1521 to 152n of the electrode layer 152.

In an embodiment, the electrode layer 152 may be disposed in the first insulating layer 151. For example, the electrodes 1521 to 152n of the electrode layer 152 may be respectively arranged in corresponding openings defined in the first insulating layer 151. In an embodiment, a portion of the first insulating layer 151 may be arranged between the electrodes 1521 to 152n to insulate each electrode from each other. In an embodiment, the electrodes 1521 to 152n of the electrode layer 152 may be arranged on the upper surface (for example, the z-direction surface) of the first insulating layer 151, and the second insulating layer 153 may cover the electrodes 1521 to 152n. In this case, a portion of the second insulating layer 153 may be placed between the electrodes 1521 to 152n to insulate each electrode from each other.

The electrostatic chuck 15 may include chuck zones Z1 to Zn. The chuck zones Z1 to Zn may overlap the electrodes 1521 to 152n. The electrodes 1521 to 152n of the electrode layer 152 may each define a corresponding chuck zone. The chuck zones Z1 to Zn may be defined by the perimeters of the electrodes 1521 to 152n. For example, a first electrode 1521 may define a first chuck zone Z1, and an nth electrode 152n may define an nth chuck zone Zn.

In the disclosure, the terms electrode and chuck zone may be used interchangeably. For example, “applying voltage to the nth chuck zone Zn” may have substantially the same meaning as “applying voltage to the nth electrode 152n.” As another example, “measuring (detecting) the current of the nth chuck zone Zn” may have substantially the same meaning as “measuring (detecting) the current of the nth electrode 152n.” As another example, “connected to the nth chuck zone Zn” may have substantially the same meaning as “connected to the nth electrode 152n.”

A constant voltage may be applied to each of the chuck zones Z1 to Zn. In other words, a constant voltage may be applied to each of the electrodes 1521 to 152n. In an embodiment, magnitudes of voltages applied to the chuck zones Z1 to Zn may be different from each other. In an embodiment, polarities of the voltages applied to the chuck zones Z1 to Zn may be different from each other. In an embodiment, a positive voltage may be applied to a number of the chuck zones Z1 to Zn, while a negative voltage may be applied to others.

In an embodiment, a chuck zone to which a positive voltage is applied (hereinafter, referred to as a positive chuck zone) and a chuck zone to which a negative voltage is applied (hereinafter, referred to as a negative chuck zone) may be arranged alternately. For example, referring to FIG. 2, a positive voltage may be applied to odd-numbered chuck zones (for example, the first chuck zone Z1, the third chuck zone Z3, etc.), and a negative voltage may be applied to even-numbered chuck zones (for example, the second chuck zone Z2, etc.). In this case, in case that n is even, a negative voltage will be applied to the nth chuck zone Zn and the n−2th chuck zone Zn−2, and a positive voltage will be applied to the n−1th chuck zone Zn−1. Conversely, in case that n is odd, a positive voltage will be applied to the nth chuck zone Zn and the n−2th chuck zone Zn−2, and a negative voltage will be applied to the n−1th chuck zone Zn−1.

In another example, a negative voltage may be applied to odd-numbered chuck zones (for example, the first chuck zone Z1, the third chuck zone Z3, etc.), and a positive voltage may be applied to even-numbered chuck zones (for example, the second chuck zone Z2, etc.). In this case, in case that n is even, a positive voltage will be applied to the nth chuck zone Zn and the n−2th chuck zone Zn−2, and a negative voltage will be applied to the n−1th chuck zone Zn−1. Conversely, in case that n is odd, a negative voltage will be applied to the nth chuck zone Zn and the n−2th chuck zone Zn−2, and a positive voltage will be applied to the n−1th chuck zone Zn−1.

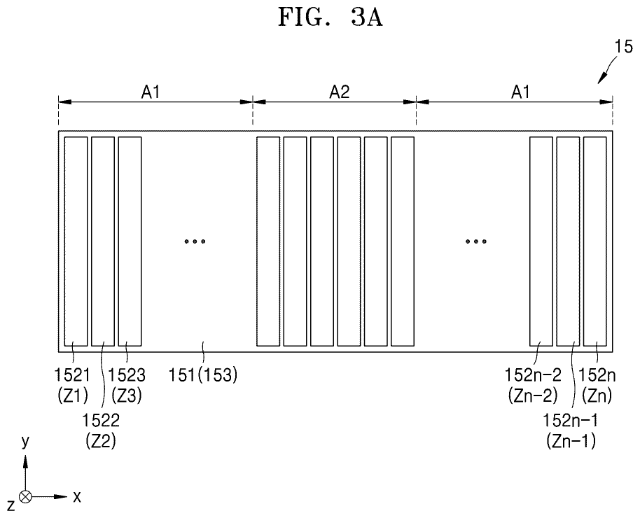

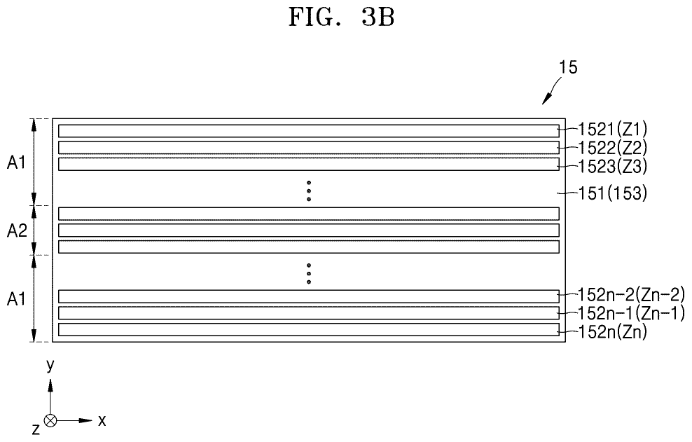

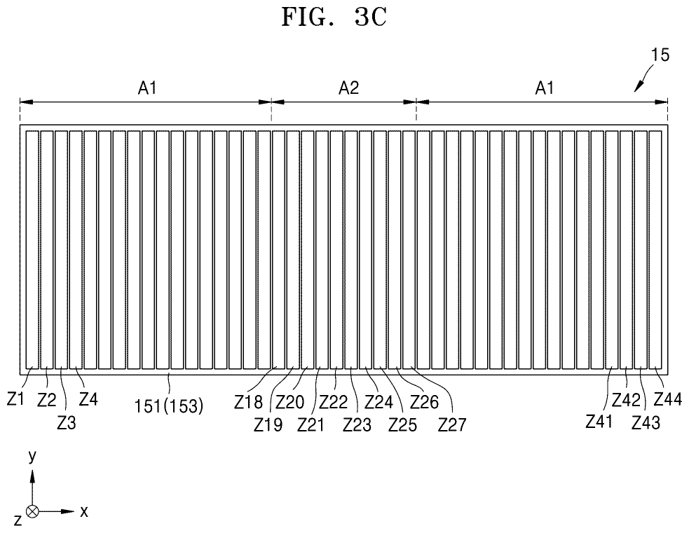

FIG. 3A is a schematic rear view of an electrostatic chuck according to an embodiment. FIG. 3B is a schematic rear view of an electrostatic chuck according to an embodiment. FIG. 3C is a schematic rear view of an electrostatic chuck according to an embodiment.

Referring to FIGS. 3A and 3B, chuck zones Z1 to Zn of the electrostatic chuck 15 may extend along one direction or a direction and may be arranged along another direction. Referring to FIG. 3A, the chuck zones Z1 to Zn may have a rectangular shape extending along the y direction and may be arranged along the x direction. Referring to FIG. 3B, the chuck zones Z1 to Zn may have a rectangular shape extending along the x direction and may be arranged along the y direction.

Obviously, the chuck zones Z1 to Zn of the disclosure is not limited to this shape. In an embodiment, the chuck zones may have any other arbitrary shape, such as a polygonal shape, a circular shape, an elliptical shape, or an irregular shape. Although FIGS. 3A and 3B illustrate chuck zones Z1 to Zn arranged to form one row along one direction or a direction (for example, the x direction or the y direction), the disclosure is not necessarily limited thereto. In an embodiment, the chuck zones Z1 to Zn may form a single row arranged along one direction or a direction (for example, the x direction), and the electrostatic chuck 15 may have such rows, and the rows may be arranged along another direction (for example, the y direction). In other words, the chuck zones Z1 to Zn may be arranged not only along either the x direction or the y direction, but also along both the x direction and the y direction.

In an embodiment, the electrostatic chuck 15 may include a first area A1 and a second area A2. The first area A1 and the second area A2 may be arranged along one direction or a direction. For example, the first area A1 and the second area A2 may be arranged along a direction along which the chuck zones Z1 to Zn may be arranged. Referring to FIG. 3A, a first area A1, a second area A2, and the first area A1 may be sequentially arranged along the x direction. Referring to FIG. 3B, a first area A1, a second area A2, and the first area A1 may be sequentially arranged along the y direction. For example, the second area A2 may be arranged in the first area A1.

The second area A2 may be defined as a region in which chuck zones, of the chuck zones Z1 to Zn arranged along one direction or a direction, that are arranged relatively close to the center of the electrostatic chuck 15 are arranged. For example, the second area A2 may be understood as the center area. The first area A1 may be understood as an area arranged outside of the center area (for example, the second area A2), for example, a side area. In FIG. 3A, a total of six chuck zones are arranged in the second area A2, and in FIG. 3B, a total of three chuck zones are arranged in the second area A2, but this is an example and the disclosure is not limited thereto. The second area A2 may be an area where the display substrate D (refer to FIG. 1) is vulnerable to sagging.

Referring now to FIG. 3C, FIG. 3C illustrates an electrostatic chuck 15 including 44 chuck zones Z1 to Z44 extending along the y direction and arranged along the x direction. As described above, it may be understood that including 44 chuck zones means including 44 electrodes. A first chuck zone Z1 to a 44th chuck zone ZA4 may be arranged along the x direction. An 18th chuck zone Z18 to a 27th chuck zone Z27 may be arranged in the second area A2. In other words, the area where the 18th chuck zone Z18 to the 27th chuck zone Z27 are arranged may be defined as the second area A2. Obviously, this is only an example, and in an embodiment, an area where a 19th chuck zone Z19 to a 26th chuck zone Z26 are arranged may be defined as the second area, and in an embodiment, an area where a 20th chuck zone Z20 to a 25th chuck zone Z25 are arranged may be defined as the second area.

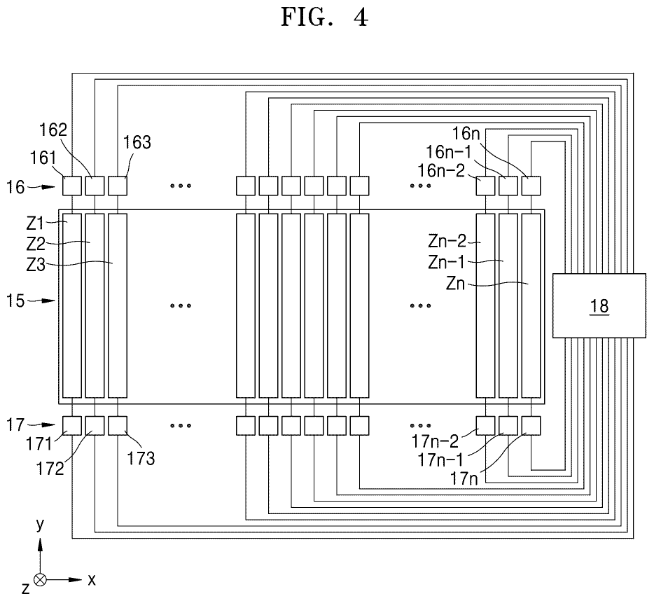

FIGS. 4 to 7 are schematic diagrams of electrostatic chuck systems according to embodiments.

An electrostatic chuck system may include an electrostatic chuck 15, a detection portion 16, a power portion 17, and a control portion 18, and may include lines connecting each component. The aforementioned apparatus 10 for manufacturing a display device (refer to FIG. 1) may be equipped with one or more electrostatic chuck systems.

FIG. 4 is a schematic diagram of an electrostatic chuck system according to an embodiment.

Referring to FIG. 4, the electrostatic chuck 15 may have chuck zones Z1 to Zn. For example, the electrostatic chuck 15 may have a first chuck zone Z1 to an nth chuck zone Zn. As described above, the electrostatic chuck 15 may include electrodes corresponding to each of the chuck zones Z1 to Zn. FIG. 4 illustrates an example in which the chuck zones Z1 to Zn extends along the y direction and is arranged along the x direction.

The detection portion 16 may include sensors 161 to 16n. For example, the detection portion 16 may include a first sensor 161 to an nth sensor 16n. In an embodiment, the number of the chuck zones Z1 to Zn of the electrostatic chuck 15 and the number of the sensors 161 to 16n of the detection portion 16 may be equal. In an embodiment, the sensors 161 to 16n of the detection portion 16 may be connected one-to-one to a corresponding chuck zone among the chuck zones Z1 to Zn. The first sensor 161 may be connected to the first chuck zone Z1. A second sensor 162 may be connected to a second chuck zone Z2. A third sensor 163 can be connected to a third chuck zone Z3. An n−2th sensor 16n−2 may be connected to an n−2th chuck zone Zn−2. An n−1th sensor 16n−1 may be connected to an n−1th chuck zone Zn−1. The nth sensor 16n may be connected to the nth chuck zone Zn.

In an embodiment, the sensors 161 to 16n may detect current, voltage, charge, etc. of the chuck zone to which each sensor is connected so as to obtain information. In an embodiment, the sensors 161 to 16n may be connected to the control portion 18. In an embodiment, the sensors 161 to 16n may transmit the information to the control portion 18.

The power portion 17 may include power sources 171 to 17n. For example, the power portion 17 may include a first power source 171 to an nth power source 17n. In an embodiment, the number of the chuck zones Z1 to Zn of the electrostatic chuck 15 and the number of the power sources 171 to 17n of the power portion 17 may be equal. In an embodiment, the power sources 171 to 17n of the power portion 17 may be connected one-to-one to corresponding chuck zones among the chuck zones Z1 to Zn. The first power source 171 may be connected to the first chuck zone Z1. A second power source 172 may be connected to the second chuck zone Z2. A third power source 173 may be connected to the third chuck zone Z3. An n−2th power source 17n−2 may be connected to the n−2th chuck zone Zn−2. An n−1th power source 17n−1 may be connected to the n−1th chuck zone Zn−1. The nth power source 17n may be connected to the nth chuck zone Zn.

In an embodiment, the power sources 171 to 17n may each supply power to a connected chuck zone. For example, the power sources 171 to 17n may each apply voltage to a connected chuck zone. In an embodiment, the power sources 171 to 17n may be connected to the control portion 18. In an embodiment, the polarity and/or magnitude of the voltage applied by each of the power sources 171 to 17n to a corresponding chuck zone may be controlled by the control portion 18. In an embodiment, each of the power sources 171 to 17n may be individually controlled by the control portion 18.

The control portion 18 may be connected to the sensors 161 to 16n of the detection portion 16 and the power sources 171 to 17n of the power portion 17. The control portion 18 may control the power sources 171 to 17n based on information (for example, current, voltage, charge of the chuck zone, etc.) received from the sensors 161 to 16n.

In an embodiment, the control portion 18 may receive information about the chuck zones Z1 to Zn from the sensors 161 to 16n. Based on the information, the control portion 18 may detect, among the chuck zones Z1 to Zn, a defective chuck zone in which an error has occurred. The control portion 18 may control (for example, cut off) voltage applied to the defective chuck zone by manipulating the power source connected to the defective chuck zone. At substantially the same time, the control portion 18 may also manipulate power source(s) connected to other chuck zone(s) adjacent to the defective chuck zone to adjust (for example, increase) voltage applied to the other adjacent chuck zone(s).

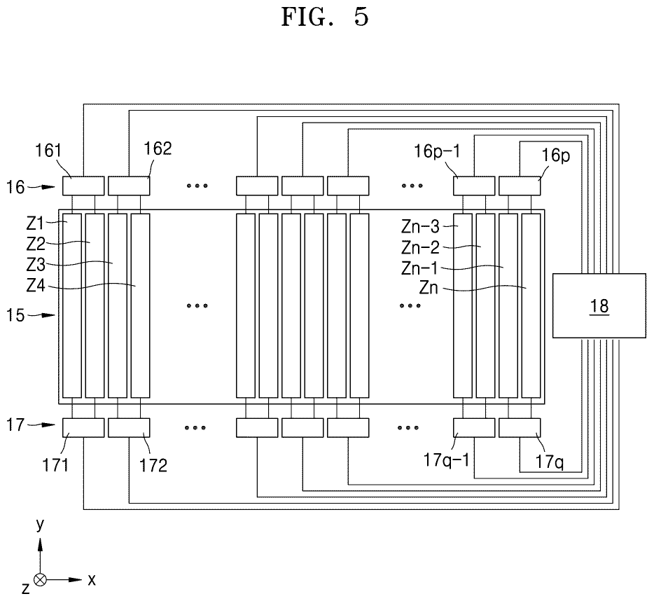

FIG. 5 is a schematic diagram of an electrostatic chuck system according to an embodiment.

It should be noted that the embodiment illustrated in FIG. 5 differs from the embodiment illustrated in FIG. 4 in a number of sensors 161 to 16p of the detection portion 16 and a number of power sources 171 to 17q of the power portion 17.

The detection portion 16 may include p sensors 161 to 16p. The power portion 17 may include power sources 171 to 17q. The electrostatic chuck 15 may have n chuck zones Z1 to Zn, similar to that of the embodiment illustrated in FIG. 4.

In an embodiment, p may be less than n. In an embodiment, at least one of the sensors 161 to 16p may be connected to two or more chuck zones. For example, a first sensor 161 may be connected to a first chuck zone Z1 and a second chuck zone Z2. A second sensor 162 may be connected to a third chuck zone Z3 and a fourth chuck zone Z4. A p−1th sensor 16p−1 may be connected to an n−3th chuck zone Zn−3 and an n−2th chuck zone Zn−2. A pth sensor 16p may be connected to an n−1th chuck zone Zn−1 and an nth chuck zone Zn. Therefore, it may be understood that FIG. 5 illustrates an embodiment in which p is half of n. Obviously, the disclosure is not limited to such numbers, and may include various embodiments in which one sensor is connected to multiple chuck zones.

In an embodiment, a sensor connected to multiple chuck zones may detect information (for example, current, voltage, charge, etc.) of each chuck zone individually and provide the information to the control portion 18. For example, the first sensor 161 may obtain information of the first chuck zone Z1 and information of the second chuck zone Z2 individually and provide them to the control portion 18.

In an embodiment, q may be less than n. In an embodiment, at least one of the power sources 171 to 17q may be connected to two or more chuck zones. For example, a first power source 171 may be connected to the first chuck zone Z1 and the second chuck zone Z2. A second power source 172 may be connected to the third chuck zone Z3 and the fourth chuck zone Z4. A q−1th power source 17q−1 may be connected to the n−3th chuck zone Zn−3 and the n−2 chuck zone Zn−2. A qth power source 17q may be connected to the n−1th chuck zone Zn−1 and the nth chuck zone Zn. Therefore, it may be understood that FIG. 5 illustrates an embodiment in which q is half of n. Obviously, the disclosure is not limited to such numbers, and may include various embodiments in which one power source is connected to multiple chuck zones.

In an embodiment, a power source connected to multiple chuck zones may apply voltage to each chuck zone individually. For example, the first power source 171 may apply different voltages to the first chuck zone Z1 and the second chuck zone Z2. By way of example, the first power source 171 may apply the same voltage to the first chuck zone Z1 and the second chuck zone Z2. By way of example, the first power source 171 may apply voltage to the first chuck zone Z1 and cut off voltage to the second chuck zone Z2. By way of example, the first power source 171 may cut off voltage to the first chuck zone Z1 and apply voltage to the second chuck zone Z2. In an embodiment, how much voltage will be applied by a power source connected to multiple chuck zones to which chuck zone may be controlled by the control portion 18.

In an embodiment, p and q may be equal. In other words, the number of the sensors 161 to 16p and the number of the power sources 171 to 17q may be equal. In an embodiment, one sensor, one power source, and chuck zones may be grouped into one set. For example, chuck zones may be connected to a single sensor, and the same chuck zones may be connected to a single power source. For example, the first chuck zone Z1 and the second chuck zone Z2 may be simultaneously connected to the first sensor 161 and the first power source 171. As another example, the third chuck zone Z3 and the fourth chuck zone Z4 may be simultaneously connected to the second sensor 162 and the second power source 172.

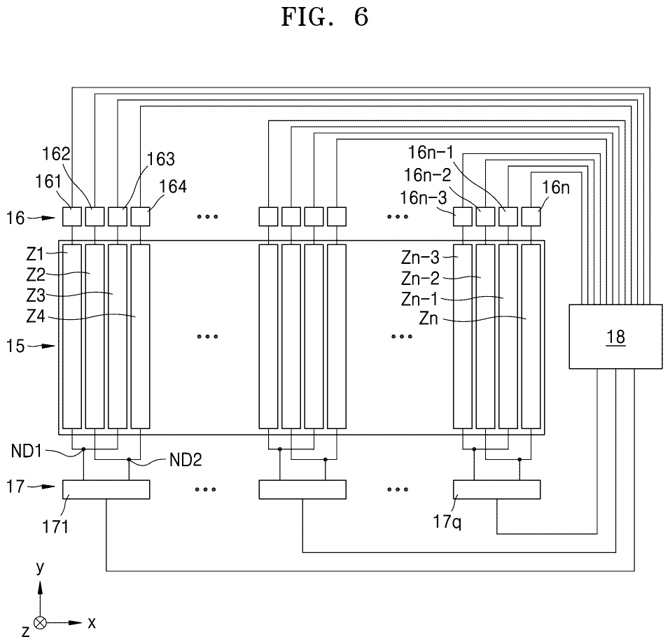

FIG. 6 is a schematic diagram of an electrostatic chuck system according to an embodiment.

In the embodiment illustrated in FIG. 6, a number of sensors 161 to 16n of the detection portion 16 may be equal to a number of chuck zones Z1 to Zn of the electrostatic chuck 15. For example, the sensors 161 to 16n and the chuck zones Z1 to Zn may correspond one-to-one.

The power portion 17 may include power sources 171 to 17q. In an embodiment, a number of the power sources 171 to 17q may be smaller than the number of the sensors 161 to 16n. In an embodiment, the number of the power sources 171 to 17q may be smaller than the number of the chuck zones Z1 to Zn.

In an embodiment, four chuck zones may be connected to a single power source. For example, a first chuck zone Z1, a second chuck zone Z2, a third chuck zone Z3, and a fourth chuck zone Z4 may be connected to a first power source 171. An n−3th chuck zone Zn−3, an n−2th chuck zone Zn−2, an n−1th chuck zone Zn−1, and an nth chuck zone Zn can be connected to a qth power source 17q. Therefore, it may be understood that FIG. 6 illustrates an embodiment in which q is a quarter of n. However, the disclosure is not necessarily limited to such numbers.

In an embodiment, two or more of the chuck zones connected to a single power source may be controlled in a synchronized manner. For example, two of the chuck zones connected to a single power source may be treated as one zone and receive the same voltage. For a detailed explanation, refer to FIG. 6.

The first chuck zone Z1, the second chuck zone Z2, the third chuck zone Z3, and the fourth chuck zone Z4 may be connected to the first power source 171. The first chuck zone Z1 and the third chuck zone Z3 may be connected to a first node ND1. The second chuck zone Z2 and the fourth chuck zone Z4 may be connected to a second node ND2. The first node ND1 and the second node ND2 may each be connected to the first power source 171. The first power source 171 may apply a constant voltage to the first node ND1. The first power source 171 may apply a constant voltage to the second node ND2. The voltage applied to the first node ND1 and the voltage applied to the second node ND2 may be individually controlled (for example, by the control portion 18). The voltage applied to the first node ND1 is equally applied to the first chuck zone Z1 and the third chuck zone Z3. The voltage applied to the second node ND2 is equally applied to the second chuck zone Z2 and the fourth chuck zone ZA.

An embodiment may thereby reduce the number of power sources required to apply voltage to each chuck zone.

Obviously, the disclosure is not necessarily limited to the arrangement shown in FIG. 6. In an embodiment, a number of chuck zones other than four may be connected to a single power source. In an embodiment, a number of chuck zones other than two may be connected to a single node. In an embodiment, a number of nodes other than two may be connected to a single power source. In an embodiment, chuck zones connected to one node do not necessarily have to have other chuck zones connected other nodes between them, and may be adjacent to each other.

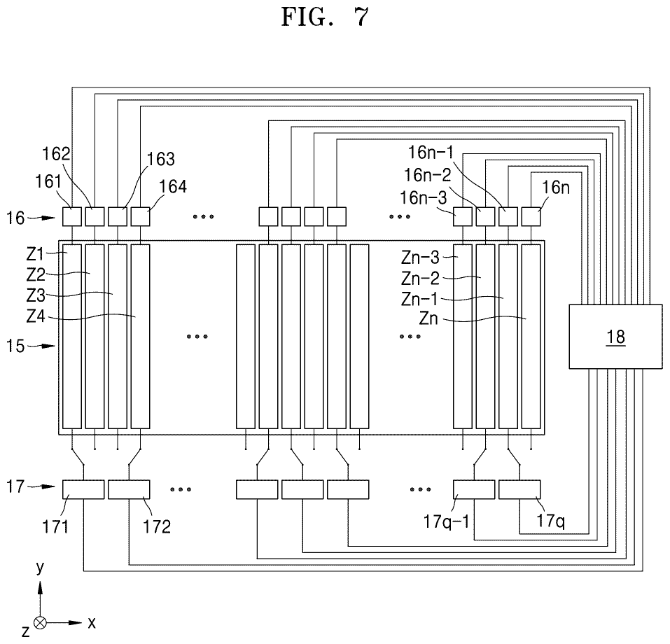

FIG. 7 is a schematic diagram of an electrostatic chuck system according to an embodiment.

In the embodiment illustrated in FIG. 7, a number of sensors 161 to 16n of the detection portion 16 may be equal to a number of chuck zones Z1 to Zn of the electrostatic chuck 15. For example, the sensors 161 to 16n and the chuck zones Z1 to Zn may correspond one-to-one.

The power portion 17 may include power sources 171 to 17q. In an embodiment, a number of the power sources 171 to 17q may be smaller than the number of the sensors 161 to 16n. In an embodiment, the number of the power sources 171 to 17q may be smaller than the number of the chuck zones Z1 to Zn.

In an embodiment, two chuck zones may be connected to a single power source. For example, a first chuck zone Z1 and a second chuck zone Z2 may be connected to a first power source 171. A third chuck zone Z3 and a fourth chuck zone 74 may be connected to a second power source 172. An n−3th chuck zone Zn−3 and an n−2th chuck zone Zn−2 may be connected to a q−1th power source 17q−1. An n−1th chuck zone Zn−1 and an nth chuck zone Zn may be connected to a qth power source 17q. Therefore, it may be understood that FIG. 7 illustrates an embodiment in which q is half of n. However, the disclosure is not necessarily limited to such numbers.

In an embodiment, each power source may have a switching circuit configured to switch between connected chuck zones. For example, the first power source 171 may have a switching circuit configured to switch between the first chuck zone Z1 and the second chuck zone Z2. FIG. 7 illustrates a state in which the first power source 171 is connected to the first chuck zone Z1. The second power source 172 may have a switching circuit configured to switch between the third chuck zone Z3 and the fourth chuck zone Z4. FIG. 7 illustrates a state in which the second power source 172 is connected to the fourth chuck zone Z4. The q−1th power source 17q−1 may have a switching circuit configured to switch between the n−3th chuck zone Zn−3 and the n−2th chuck zone Zn−2. FIG. 7 illustrates a state in which the q−1th power source 17q−1 is connected to the n−2th chuck zone Zn−2. The qth power source 17q may have a switching circuit configured to switch between the n−1th chuck zone Zn−1 and the nth chuck zone Zn. FIG. 7 illustrates a state in which the qth power source 17q is connected to the n−1th chuck zone Zn−1.

By providing such a switching circuit, an embodiment may reduce the number of power sources required to apply voltage to each chuck zone.

Obviously, the disclosure is not necessarily limited to the arrangement shown in FIG. 7. In an embodiment, a number of chuck zones other than two may be connected to a single power source. In an embodiment, a single power source may have a switching circuit that switches between a number of chuck zones other than two. In an embodiment, a single power source may have two or more switching circuits. In an embodiment, the chuck zones connected to a single power source through a single switching circuit do not need to be adjacent to one another, but may be spaced apart from one another, such as with another chuck zone between them.

A method of driving the electrostatic chuck system having the structures described above will be described hereinafter in detail together with other operations of the method of manufacturing a display device. Obviously, the method of driving the electrostatic chuck system may also be a part of the method of manufacturing a display device.

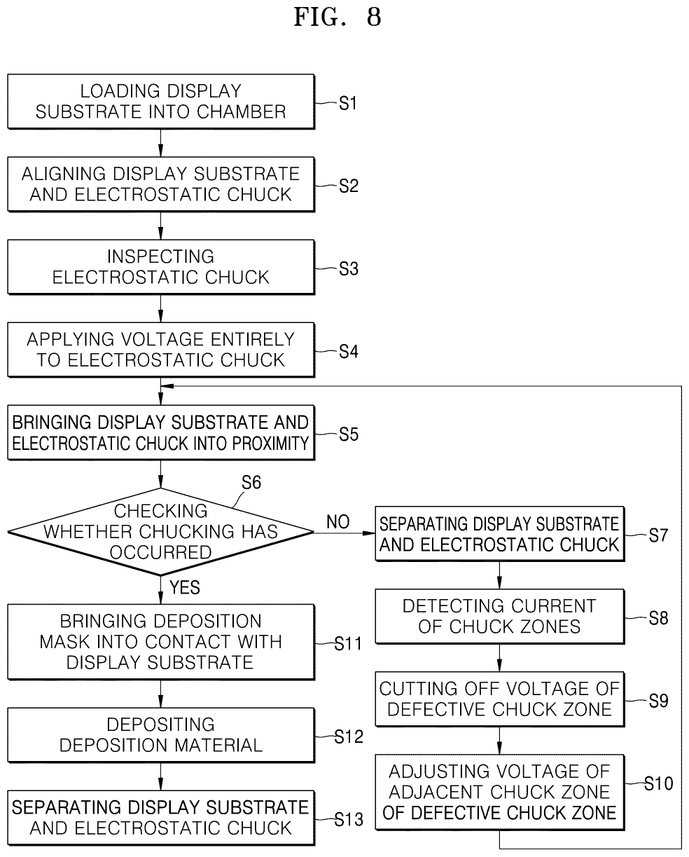

FIG. 8 is a flowchart of operations of a method of manufacturing a display device according to an embodiment.

Referring to FIGS. 1 and 8 together, the apparatus 10 for manufacturing a display device may be used to manufacture a display device as described below.

In case that the pressure control portion 20 makes the inside of the chamber 11 to a pressure equal to or similar to atmospheric pressure, the gate valve 111 may operate so as to open the opened portion of the chamber 11.

Thereafter, in a first operation S1, the display substrate D may be loaded into the chamber 11 from outside the chamber 11. In this case, the display substrate D may be loaded into the chamber 11 in various ways. For example, the display substrate D may be loaded into the chamber 11 from outside the chamber 11 by means of a robot arm or the like arranged outside of the chamber 11. In an embodiment, in case that the first support portion 12 is formed in the form of a shuttle, after the first support portion 12 is taken out from inside the chamber 11 to outside the chamber 11, the display substrate D may be secured on the first support portion 12 by a separate robot arm or the like arranged outside of the chamber 11, and the first support portion 12 may be loaded into the chamber 11 from outside the chamber 11. For convenience of explanation, the following description will focus on a case in which the display substrate D is loaded into the chamber 11 from outside the chamber 11 by a robot arm arranged outside of the chamber 11. In case that the display substrate D is loaded into the chamber 11, the display substrate D may be secured on the first support portion 12.

The deposition mask 14 may be arranged inside of the chamber 11. In an embodiment, the deposition mask 14 may be loaded into the chamber 11 from outside the chamber 11 in the same or similar manner as that of the display substrate D. Hereinafter, for convenience of explanation, a detailed description will be given of a case in which only the display substrate D is loaded into the chamber 11 from outside of the chamber 11 while the deposition mask 14 is arranged inside of the chamber 11.

Thereafter, in a second operation S2, the display substrate D and the electrostatic chuck 15 may be aligned. In this case, the vision portion 22 may capture positions of the display substrate D and the electrostatic chuck 15. In an embodiment, the vision portion 22 may film a first alignment mark of the display substrate D and a second alignment mark of the electrostatic chuck 15. The positions of the display substrate D and the electrostatic chuck 15 may be identified based on the filmed first alignment mark and second alignment mark. Once the positions of the display substrate D and the electrostatic chuck 15 are identified, the position of the display substrate D and/or the position of the electrostatic chuck 15 may be fine-tuned.

Afterwards, in a third operation S3, the electrostatic chuck 15 may be inspected before chucking. At this operation, a given voltage may be applied to the electrostatic chuck 15 to check whether defects such as arcing and/or short circuit occur. In case that a defect such as the above occurs, the operation of the apparatus 10 for manufacturing a display device may be stopped. In an embodiment, in the third operation S3, additionally, a voltage required to chuck the display substrate D may be calculated. In this case, the voltage required to chuck the display substrate D may vary depending on the weight of the display substrate D, for example, the size of the display substrate D. In an embodiment, after calculating the voltage required, it may be applied to the electrostatic chuck 15 to check whether a defect occurs.

Afterwards, in a fourth operation S4, voltage may be applied to the entire electrostatic chuck 15. The above voltage may be a constant voltage and may be the same voltage in the chuck zones described above. In an embodiment, the constant voltage may have a constant absolute value, and the voltage applied to the chuck zones may have different polarities depending on the chuck zone.

Thereafter, in a fifth operation S5, the electrostatic chuck 15 and the display substrate D may be brought into proximity. In an embodiment, the electrostatic chuck 15 may be lowered, for example moved in the opposite direction of the z direction, to be brought into proximity with the display substrate D. In an embodiment, the first support portion 12 and the display substrate D may be raised, for example moved in the z direction, to be brought into proximity with the electrostatic chuck 15. In an embodiment, the electrostatic chuck 15 and the first support portion 12 may be moved toward each other simultaneously to bring the electrostatic chuck 15 and the display substrate D into proximity. In an embodiment, the electrostatic chuck 15 and the display substrate D may be brought into proximity until they come into contact with each other.

Afterwards, in a sixth operation S6, whether chucking has occurred may be checked. In an embodiment, whether chucking has occurred may be checked by examining whether each of the chuck zones of the electrostatic chuck 15 is in close contact with the display substrate D. In an embodiment, whether chucking has occurred may be checked by examining the chuck zones of the electrostatic chuck 15 using the sensors of the detection portion 16. In an embodiment, whether chucking (close contact) has occurred may be checked by measuring the charge of each of the chuck zones of the electrostatic chuck 15 using the sensors of the detection portion 16.

After checking whether chucking has occurred, in case that chucking is complete, an eleventh operation S11 may be performed. In case that chucking is not complete, a seventh operation S7 may be performed.

In the seventh operation S7, the electrostatic chuck 15 and the display substrate D may be separated. In an embodiment, the electrostatic chuck 15 may be raised, for example moved in the z direction, to be separated from the display substrate D. In an embodiment, the first support portion 12 and the display substrate D may be lowered, for example moved in the opposite direction of the z direction, to be separated from the electrostatic chuck 15. In an embodiment, the electrostatic chuck 15 and the first support portion 12 may be simultaneously moved away from each other to separate the electrostatic chuck 15 and the display substrate D.

In an eighth operation S8, current of the chuck zones of the electrostatic chuck 15 may be detected. In an embodiment, the current of the chuck zones of the electrostatic chuck 15 may be detected using the sensors of the detection portion 16. There may be a chuck zone (hereinafter referred to as a defective chuck zone) in which short circuits or other defects occur due to insufficient insulation from surrounding chuck zones. In this case, an abnormality in the current of the defective chuck zone may be detected by the sensor connected to the defective chuck zone. Information such as existence of the defective chuck zone where the abnormality in current has occurred, value of the current in the defective chuck zone, and location of the defective chuck zone etc. may be transmitted to the control portion 18 from a sensor connected to the defective chuck zone.

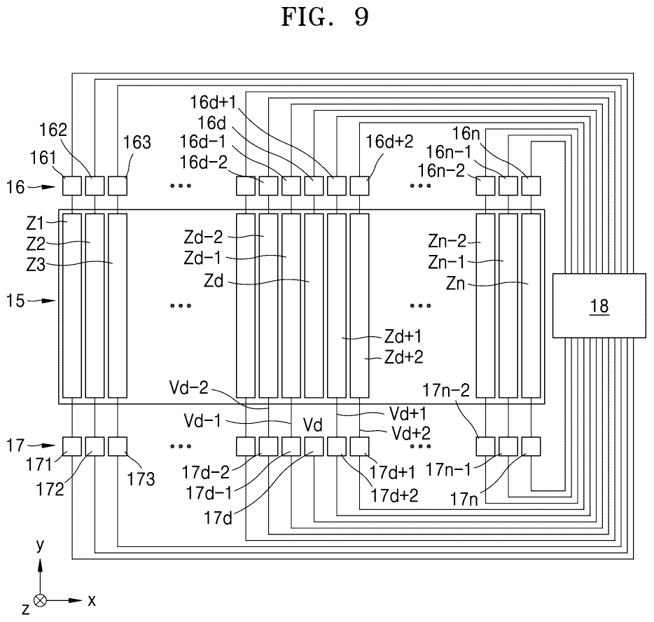

In this case, in a ninth operation S9 and a tenth operation S10, the control portion 18 may control the power portion 17 to adjust voltage applied to the defective chuck zone and other chuck zones adjacent to the defective chuck zone. For example, the control portion 18 may control the power sources of the power portion 17. This controlling process is described in detail below with reference to FIG. 9.

FIG. 9 is a schematic diagram of operations (for example, the ninth operation S9 and the tenth operation S10) of the method of manufacturing a display device according to an embodiment.

Referring to FIGS. 1, 8, and 9 together, an embodiment will be described in which the electrostatic chuck 15 may include n chuck zones Z1 to Zn, the detection portion 16 may include n sensors 161 to 16n, and the power portion 17 may include n power sources 171 to 17n. In an embodiment, each of the n chuck zones Z1 to Zn, the n sensors 161 to 16n, and the n power sources 171 to 17n may be connected one-to-one. Obviously, the disclosure is not necessarily limited to such structure.

In case that a defective chuck zone Zd exists among the chuck zones Z1 to Zn, the sensor 16d connected to the defective chuck zone Zd may transmit corresponding information (for example, current of the defective chuck zone Zd) to the control portion 18. Information transfer may take place in the eighth operation S8.

In the ninth operation S9, the control portion 18 may control the power source 17d connected to the defective chuck zone Zd to cut off the voltage Vd applied to the defective chuck zone Zd. In other words, the control portion 18 may adjust the voltage Vd applied to the defective chuck zone Zd to 0. To represent the voltage cutoff, the defective chuck zone Zd and the corresponding power source 17d are shown as not being connected in FIG. 9. In this case, electrostatic force may not be generated between a portion of the display substrate D overlapping the defective chuck zone Zd and the electrostatic chuck 15. Accordingly, the portion of the display substrate D may not be in close contact with the electrostatic chuck 15 and may sag. To prevent this, the control portion 18 may proceed to the tenth operation S10.

In the tenth operation S10, the control portion 18 may adjust voltages applied to chuck zones Zd−2, Zd−1, Zd+1, and Zd+2 adjacent to the defective chuck zone Zd (hereinafter, adjacent chuck zones). In an embodiment, the description is based on four adjacent chuck zones Zd−2, Zd−1, Zd+1, and Zd+2, but the disclosure is not necessarily limited thereto. The control portion 18 may increase the voltages applied to the adjacent chuck zones Zd−2, Zd−1, Zd+1, and Zd+2. For example, the control portion 18 may increase the voltages applied to the adjacent chuck zones Zd−2, Zd−1, Zd+1, and Zd+2 by adjusting the power sources Vd−2, Vd−1, Vd+1, and Vd+2 respectively connected to the adjacent chuck zones Zd−2, Zd−1, Zd+1, and Zd+2. In an embodiment, there may be a difference in the amount of increase of the voltage applied to each of the adjacent chuck zones Zd−2, Zd−1, Zd+1, and Zd+2. In an embodiment, voltage increase in chuck zones Zd−1 and Zd+1 immediately adjacent to the defective chuck zone Zd may be greater than voltage increase in other adjacent chuck zones Zd−2 and Zd+2. In an embodiment, the voltage increase in chuck zones Zd−1 and Zd+1 immediately adjacent to the defective chuck zone Zd may be smaller than the voltage increase in other adjacent chuck zones Zd−2 and Zd+2.

As the voltages applied to the adjacent chuck zones Zd−2, Zd−1, Zd+1, and Zd+2 are increased, electrostatic force between a portion of the display substrate D overlapping the adjacent chuck zones Zd−2, Zd−1, Zd+1, and Zd+2 and the electrostatic chuck 15 may increase. Accordingly, electrostatic force between the display substrate D and the electrostatic chuck 15 in an area adjacent to the defective chuck zone Zd may be strengthened. Accordingly, even in case that a defective chuck zone Zd occurs, contact between the display substrate D and the electrostatic chuck 15 may be maintained in the defective chuck zone Zd.

After the voltage of the defective chuck zone Zd is cut off in the ninth operation S9, and the voltages of the adjacent chuck zones Zd−2, Zd−1, Zd+1, and Zd+2 are increased in the tenth operation S10, the fifth operation S5 may be performed again to bring the display substrate D and the electrostatic chuck 15 into proximity. After performing the fifth operation S5 again, the sixth operation S6 may be performed again to check whether chucking has occurred. Optionally, the eighth operation S8 may be repeated to check the electrostatic chuck 15 again for additional defects.

After the contact of the display substrate D and the electrostatic chuck 15 has been completed, in an eleventh operation S11, the deposition mask 14 may be brought to contact with the display substrate D.

In this case, an operation of aligning the display substrate D and the deposition mask 14 may be further performed. In an embodiment, the vision portion 22 may film the first alignment mark of the display substrate D and a third alignment mark of the deposition mask 14. The positions of the display substrate D and the deposition mask 14 may be confirmed and fine-tuned based on the filmed first alignment mark and third alignment mark.

In an embodiment, the second support portion 13 and the deposition mask 14 may be moved (for example, in the z direction) toward the display substrate D which is in close contact with the electrostatic chuck 15. In order to bring the deposition mask 14 into close contact with the display substrate D, the electrostatic force of the electrostatic chuck 15 and/or the magnetic force of the magnetic force portion 19 may be applied to the deposition mask 14.

After alignment and contact of the display substrate D and the deposition mask 14 has been completed, a deposition material may be deposited in a twelfth operation S12. The deposition source 21 may operate to spray the deposition material toward the deposition mask 14 (for example, in the z direction), and the deposition material passing through the openings 141 of the deposition mask 14 may be deposited on the display substrate D. In this case, the pressure control portion 20 may maintain pressure inside the chamber 11 in a vacuum-like or similar state by sucking in the gas inside the chamber 11 and discharging it to the outside.

The deposition material may be deposited on the display substrate D through the openings 141 of the deposition mask 14. The openings 141 of the deposition mask 14 may be formed to correspond to a designed deposition area, so as to provide a deposition area that is identical or similar to the designed deposition area.

Thereafter, in a thirteenth operation S13, the display substrate D, the electrostatic chuck 15, and the deposition mask 14 may be separated from each other. In an embodiment, the display substrate D and/or the deposition mask 14 may be withdrawn from the chamber 11. For example, in the case of the display substrate D, it may be taken out of the chamber 11 for a next process. Obviously, the deposition process may be repeated multiple times before the display substrate D is taken out of the chamber 11, and multiple deposition layers may be disposed on the display substrate D. As another example, in the case of the deposition mask 14, the deposition mask 14 may be withdrawn from the chamber 11 for cleaning the deposition material remaining on the surface of the deposition mask 14. Obviously, the deposition mask 14 may be used to form multiple display substrates D or multiple deposition layers before being withdrawn from the chamber 11.

Through the above process, the apparatus 10 for manufacturing a display device may deposit deposition material on the display substrate D in an area identical to or similar to a designed shape.

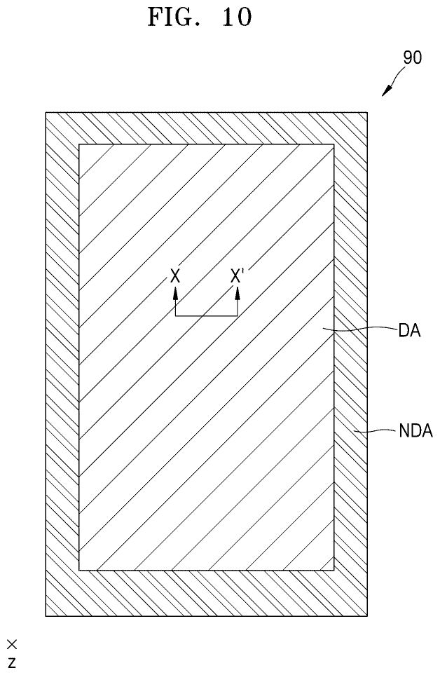

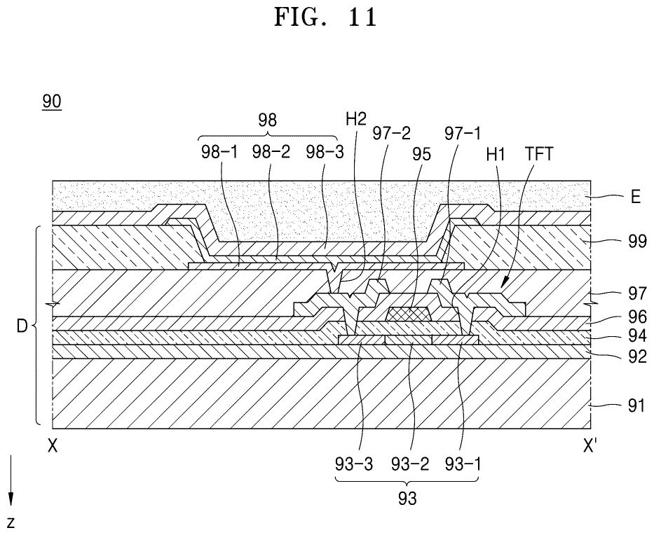

FIG. 10 is a schematic plan view of a display device manufactured using an apparatus for manufacturing a display device according to an embodiment. FIG. 11 is a schematic cross-sectional view of the display device taken along line X-X′ of FIG. 10.

Referring to FIGS. 10 and 11, a display device 90 may have a display area DA and a non-display area NDA defined on a substrate 91, the non-display area NDA arranged around the display area DA. A light-emitting element 98 may be arranged in the display area DA, and power wiring (not shown) may be arranged in the non-display area NDA.

Deposition material patterns may be arranged in the display area DA. Although FIG. 10 illustrates the display device 90 and the display area DA having a substantially quadrangular shape, the disclosure is not limited thereto. The display area DA may have another shape, for example, an irregular shape.

The display device 90 may include a display substrate D, an intermediate layer 98-2 disposed on the display substrate D, and an opposite electrode 98-3 disposed on the intermediate layer 98-2. The display device 90 may include a thin-film encapsulation layer E disposed on the opposite electrode 98-3.

The display substrate D may include the substrate 91, a thin-film transistor TFT, a via layer 97, and a pixel electrode 98-1.

The substrate 91 may include plastic material or metal material. The substrate 91 may include polyimide (PI).

The thin-film transistor TFT may be disposed over the substrate 91, the via layer 97 may cover the thin-film transistor TFT, and the light-emitting element 98 may be disposed on the via layer 97.

A buffer layer 92 including an organic compound and/or an inorganic compound may be further disposed on the substrate 91, and the buffer layer 92 may include SiOₓ (x>1) and/or SiNₓ (x≥1).

After an active layer 93 arranged in a given pattern is disposed on the buffer layer 92, the active layer 93 may be buried by a gate insulating layer 94. The active layer 93 may include a source region 93-1 and a drain region 93-3 and may further include a channel region 93-2 therebetween.

This active layer 93 may include various materials. In an embodiment, the active layer 93 may include an inorganic semiconductor material such as amorphous silicon or crystalline silicon. In an embodiment, the active layer 93 may include an oxide semiconductor. In an embodiment, the active layer 93 may include an organic semiconductor material. However, a case where the active layer 93 is formed of amorphous silicon will be mainly described below for convenience.

The active layer 93 may be formed by forming an amorphous silicon layer on the buffer layer 92, crystallizing the amorphous silicon layer into a polycrystalline silicon layer, and patterning the polycrystalline silicon layer. The active layer 93 may have the source region 93-1 and the drain region 93-3 doped with impurities depending on the type of a thin-film transistor such as a driving thin-film transistor (not shown), a switching thin-film transistor (not shown), etc.

A gate electrode 95 corresponding to the active layer 93 and an interlayer insulating layer 96 burying the gate electrode 95 may be disposed on the gate insulating layer 94. After a contact hole Hl is formed in the interlayer insulating layer 96 and the gate insulating layer 94, a source electrode 97-1 and a drain electrode 97-2 may be disposed on the interlayer insulating layer 96 to be in contact with the source region 93-1 and the drain region 93-3, respectively.

The via layer 97 is disposed over the thin-film transistor TFT, and the pixel electrode 98-1 of the light-emitting element 98 is disposed on the via layer 97. The pixel electrode 98-1 is in contact with the drain electrode 97-2 of the thin-film transistor TFT through a via hole H2 in the via layer 97. The via layer 97 may be formed of an inorganic material and/or an organic material in a single layer or two or more layers, and may be a planarization layer having a flat upper surface regardless of curves in a lower layer thereof or may be curved along curves in a lower layer thereof.

After the pixel electrode 98-1 is disposed on the via layer 97, a pixel-defining layer 99 may be formed of an organic material and/or an inorganic material to cover the pixel electrode 98-1 and the via layer 97 and may have an opening to expose the pixel electrode 98-1.

The intermediate layer 98-2 and the opposite electrode 98-3 are disposed on the pixel electrode 98-1. In an embodiment, the opposite electrode 98-3 may be disposed over the entire surface of the display substrate D. In this case, the opposite electrode 98-3 may be disposed on the intermediate layer 98-2 and the pixel-defining layer 99. Hereinafter, a case where the opposite electrode 98-3 is disposed on the intermediate layer 98-2 and the pixel-defining layer 99 will be mainly described for convenience.

The pixel electrode 98-1 may serve as an anode, the opposite electrode 98-3 may serve as a cathode, and polarities of the pixel electrode 98-1 and the opposite electrode 98-3 may be reversed.

The pixel electrode 98-1 and the opposite electrode 98-3 are insulated from each other by the intermediate layer 98-2. Voltages of different polarities are applied to the intermediate layer 98-2 by the pixel electrode 98-1 and the opposite electrode 98-3, such that light emission occurs at an emission layer included in the intermediate layer 98-2.

The intermediate layer 98-2 may include an emission layer. As another optional example, the intermediate layer 98-2 may include an emission layer, and may further include at least one of a hole injection layer, a hole transport layer, an electron transport layer, and an electron injection layer. An embodiment is not limited thereto, and the intermediate layer 98-2 may include an organic emission layer and may further include a variety of other functional layers (not shown).

In this regard, the intermediate layer 98-2 may be formed through the above-described apparatus for manufacturing a display device. The intermediate layer 98-2 may include intermediate layers 98-2, and the intermediate layers 98-2 may form the display area DA. In this regard, the intermediate layers 98-2 may be apart from each other in the display area DA.

One unit pixel is made up of sub-pixels, and the sub-pixels may emit light of various colors. For example, the sub-pixels may include sub-pixels that emit red light, green light, and blue light, respectively, or may include sub-pixels (not denoted) that emit red light, green light, blue light, and white light.

The sub-pixel described above may include one intermediate layer 98-2. In this regard, in case that one sub-pixel is formed, the intermediate layer 98-2 may be formed through the above-described apparatus for manufacturing a display device.

The thin-film encapsulation layer E may include inorganic layers or may include an inorganic layer and an organic layer. The organic layer of the thin-film encapsulation layer E may be formed of a polymer, and for example, may be a single layer or a laminated layer formed of one of polyethylene terephthalate, polyimide, polycarbonate, epoxy, polyethylene, and polyacrylate. The inorganic layer of the thin-film encapsulation layer E may be a single layer or a laminated layer including metal oxide or metal nitride. For example, the inorganic layer may include one of SiNₓ, Al₂O₃, SiOₓ, and TiO₂. An externally exposed top layer of the thin-film encapsulation layer E may be an inorganic layer for preventing penetration of moisture into a light-emitting element.

The thin-film encapsulation layer E may include at least one sandwich structure with at least one organic layer between at least two inorganic layers. As another example, the thin-film encapsulation layer E may include at least one sandwich structure with at least one inorganic layer between at least two organic layers. As another example, the thin-film encapsulation layer E may include a sandwich structure with at least one organic layer between at least two inorganic layers and a sandwich structure with at least one inorganic layer between at least two organic layers.

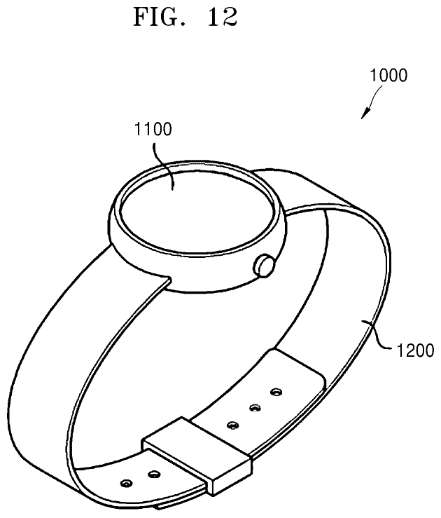

Referring to FIG. 12, the electronic device 1000 shown in FIG. 12 may be applied to a smart watch 2000 including a display part 1100 and a strap part 1200.

The smart watch 2000 may be a wearable electronic device. For example, the smart watch 2000 may have a structure in which the strap part 1200 is mounted on a wrist of a user.

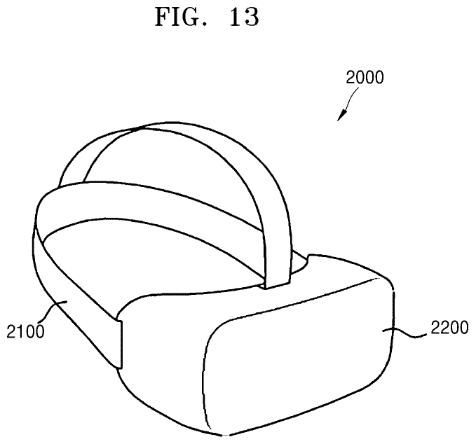

Referring to FIG. 13, the display system 1000 shown in FIG. 13 may be applied to a head mounted display device 2000.

The head mounted display device 2000 may be a wearable electronic device which can be worn on the head of a user. For example, the head mounted display device 2000 may be a wearable device for virtual reality (VR) or mixed reality (MR).

The head mounted display device 2000 may include a head mounted band 2100 and a display accommodating case 2200. The head mounted band 2100 may be connected to the display accommodating case 2200. The head mounted band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments are not limited thereto. For example, the head mounted band 2100 may be implemented in the form of a glasses frame, a helmet or the like within the spirit and the scope of the disclosure.

The electronic device may include a flat panel display, a curved display, a computer monitor, a medical monitor, a television, a billboard, an indoor light, an outdoor light, an indoor signaling light, an outdoor signaling light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, or a signboard

According to one or more embodiments as described above, an apparatus for manufacturing a display device and a method of manufacturing a display device are provided, in which a voltage applied to other chuck zones adjacent to a chuck zone where a defect has occurred is adjusted.

To compensate for the defective chuck zone not being able to provide a required chucking force to the display substrate, voltage applied to the other chuck zones adjacent to the defective chuck zone may be increased. Therefore, a chucking force applied to the display substrate in the other chuck zones adjacent to the defective chuck zone may increase. Accordingly, contact between the display substrate and the electrostatic chuck may be maintained in an area overlapping the defective chuck zone.

While one or more embodiments have been described with reference to the figures, it will be understood by one of ordinary skill in the art that various changes in form and details may be made therein. Therefore, the scope of the disclosure should be defined by the spirit and scope of the following claims.

What is claimed is:

1. An apparatus for manufacturing a display device, the apparatus comprising:
a chamber;
an electrostatic chuck disposed in the chamber, the electrostatic chuck holding a display substrate in close contact with a surface of the electrostatic chuck, and comprising a plurality of chuck zones;
a detection portion comprising a plurality of sensors connected to corresponding chuck zones among the plurality of chuck zones;
a power portion comprising a plurality of power sources connected to the plurality of chuck zones and applies voltages to the plurality of chuck zones; and
a control portion connected to the detection portion and the power portion, wherein
the control portion detects a defective chuck zone among the plurality of chuck zones based on information received from the detection portion, and controls the power portion to adjust a voltage applied to another chuck zone adjacent to the defective chuck zone.

2. The apparatus of claim 1, wherein
the detection portion has a number of sensors equal to a number of the plurality of chuck zones, and
one sensor is connected to one chuck zone.

3. The apparatus of claim 1, wherein
the power portion has a number of power sources equal to or less than a number of the plurality of chuck zones and
one power source is connected to one or more chuck zones of the plurality of chuck zones.

4. The apparatus of claim 1, wherein at least one of the plurality of power sources has a switching circuit connected to two or more of the plurality of chuck zones and controls a voltage applied to each of the plurality of chuck zones connected to the switching circuit.

5. The apparatus of claim 1, wherein the plurality of chuck zones comprises eight or more chuck zones.

6. The apparatus of claim 1, wherein at least one of the plurality of sensors detects a current in a corresponding chuck zone of the plurality of chuck zones.

7. The apparatus of claim 1, wherein the control portion cuts off a voltage in the defective chuck zone.

8. The apparatus of claim 7, wherein the control portion increases the voltage applied to the other chuck zone adjacent to the defective chuck zone.

9. The apparatus of claim 1, wherein
the plurality of chuck zones comprise positive chuck zones that receive positive voltages and negative chuck zones that receive negative voltages, and
the positive chuck zones and the negative chuck zones are alternately disposed along a direction.

10. The apparatus of claim 1, further comprising:
a deposition mask disposed in the chamber, wherein
the display substrate is disposed between the electrostatic chuck and the deposition mask.

11. A method of manufacturing a display device, the method comprising:
loading a display substrate into a chamber in which an electrostatic chuck comprising a plurality of chuck zones is disposed;
inspecting the plurality of chuck zones by using a plurality of sensors connected to corresponding chuck zones among the plurality of chuck zones;
controlling a plurality of power sources connected to the plurality of chuck zones to adjust a voltage applied to another chuck zone adjacent to a defective chuck zone among the plurality of chuck zones; and
bringing the display substrate and the electrostatic chuck into proximity to each other.

12. The method of claim 11, wherein a number of the plurality of chuck zones and a number of the plurality of sensors are equal to each other.

13. The method of claim 11, wherein
a number of the plurality of power sources is equal to or less than a number of the plurality of chuck zones, and
one power source is connected to one or more chuck zones of the plurality of chuck zones.

14. The method of claim 13, wherein at least one of the plurality of power sources has a switching circuit connected to two or more of the plurality of chuck zones and controls a voltage applied to each of the chuck zones of the plurality of chuck zones connected to the switching circuit.

15. The method of claim 11, further comprising:
applying a voltage to the plurality of chuck zones.

16. The method of claim 11, further comprising:
detecting a current of the plurality of chuck zones.

17. The method of claim 11, wherein the controlling of the plurality of power sources comprises:
cutting off a voltage of the defective chuck zone.

18. The method of claim 11, wherein the controlling of the plurality of power sources further comprises:
increasing the voltage applied to the other chuck zone adjacent to the defective chuck zone.

19. The method of claim 11, wherein the inspecting of the plurality of chuck zones comprises:
checking whether the electrostatic chuck and the display substrate are in contact with each other in each of the plurality of chuck zones.

20. The method of claim 11, further comprising:
bringing a deposition mask into contact with the display substrate; and
depositing a deposition material on the display substrate.

21. An electronic device comprising the display device manufactured by the method of claim 11.

22. The electronic device of claim 21, wherein the electronic device is at least one of a flat panel display, a curved display, a computer monitor, a medical monitor, a television, a billboard, an indoor light, an outdoor light, an indoor signaling light, an outdoor signaling light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, or a signboard.
